(19) United States
(12) Patent Application Publication
(10) Pub. No.: US 2025/0096084 A1
(43) Pub. Date: Mar. 20, 2025

(54) INTEGRATED STACKED SUBSTRATE FOR ISOLATED POWER MODULE

(71) Applicant: Texas Instruments Incorporated, Dallas, TX (US)

(72) Inventors: Vijaylaxmi Khanolkar, Pune (IN); Yi Yan, San Jose, CA (US)

(21) Appl. No.: 18/471,223

(22) Filed: Sep. 20, 2023

(51) Int. Cl. H01L 23/495; H01L 23/00; H01L 25/00; H01L 25/065; H01L 25/07

(52) U.S. Cl. CPC H01L 23/49568; H01L 23/4951; H01L 23/49513; H01L 23/49575; H01L 24/32; H01L 25/0657; H01L 25/074; H01L 25/50; H01L 23/49555; H01L 24/33; H01L 24/48; H01L 24/49; H01L 24/73; H01L 2224/32055; H01L 2224/32245; H01L 2224/33155; H01L 2224/48141; H01L 2224/48145; H01L 2224/48245; H01L 2224/4918; H01L 2224/73215; H01L 2224/73265; H01L 2924/10253; H01L 2924/1033; H01L 2924/13091

(57) ABSTRACT

A microelectronic device includes a die pad having a first surface and a second, opposite, surface. A first component is directly attached to the first surface of the die pad through a first thermally conductive material. A second component is directly attached to the second surface of the die pad through a second thermally conductive material. At least a portion of the second component overlaps at least a portion of the first component. The microelectronic device further includes a first thermal shunt connecting the die pad to a first lead, and a second thermal shunt connecting the die pad to a second lead. The first thermal shunt is closer to a center of the first component than to a center of the second component. The second thermal shunt is closer to a center of the second component than to a center of the first component.

### TECHNICAL FIELD

This disclosure relates to the field of microelectronic devices. More particularly, but not exclusively, this disclosure relates to multiple components in microelectronic devices.

### BACKGROUND

Multi-chip modules (MCMs) include two or more electronic components within a single package to reduce interconnect lengths. MCMs have found applications across diverse domains, including computing, communication, automotive, and consumer electronics. Two challenges are size reduction and thermal management.

### SUMMARY

The present disclosure introduces a microelectronic device that includes a die pad having a first surface and a second surface, opposite from the first surface. A first component is directly attached to the first surface of the die pad through a first thermally conductive material. A second component is directly attached to the second surface of the die pad through a second thermally conductive material. At least a portion of the second component overlaps at least a portion of the first component. The microelectronic device includes electrically conductive leads extending to an exterior of the microelectronic device. The microelectronic device further includes a first thermal shunt connecting the die pad to a first lead of the leads, and a second thermal shunt connecting the die pad to a second lead. The first thermal shunt is closer to a center of the first component than to a center of the second component. The second thermal shunt is closer to a center of the second component than to a center of the first component.

The present disclosure further introduces a microelectronic device that includes a first die pad having a first surface and a second surface, opposite from the first surface, and a second die pad having a third surface and a fourth surface, opposite from the third surface. The third surface is coplanar with the first surface of the first die pad, and the fourth surface is coplanar with the second surface of the first die pad. The microelectronic device includes a first component directly attached to the first surface of the first die pad through a first thermally conductive material, and a second component directly attached to the fourth surface of the second die pad through a second thermally conductive material. At least a portion of the second component overlaps at least a portion of the first component. The microelectronic device includes electrically conductive leads extending to an exterior of the microelectronic device. The microelectronic device further includes a first thermal shunt connecting the first die pad to a first lead of the leads, and a second thermal shunt connecting the second die pad to a second lead.

### BRIEF DESCRIPTION OF THE VIEWS OF THE DRAWINGS

FIG. 1A through FIG. 1H are cross sections and top views of an example microelectronic device, depicted in stages of formation.

FIG. 2A through FIG. 2F are cross sections and top views of another example microelectronic device, depicted in stages of formation.

FIG. 3A through FIG. 3F are cross sections and top views of another example microelectronic device, depicted in stages of formation.

FIG. 4A through FIG. 4F are cross sections and top views of another example microelectronic device, depicted in stages of formation.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In addition, although some of the embodiments illustrated herein are shown in two dimensional views with various regions having depth and width, it should be clearly understood that these regions are illustrations of only a portion of a device that is actually a three dimensional structure. Accordingly, these regions will have three dimensions, including length, width, and depth, when fabricated on an actual device. Moreover, while the present invention is illustrated by embodiments directed to active devices, it is not intended that these illustrations be a limitation on the scope or applicability of the present invention. It is not intended that the active devices of the present invention be limited to the physical structures illustrated. These structures are included to demonstrate the utility and application of the present invention to presently preferred embodiments.

In one aspect, a microelectronic device includes a die pad having a first surface and a second surface opposite from the first surface. The die pad is electrically conductive. The microelectronic device includes a first component directly attached to the first surface of the die pad through a first thermally conductive material. The microelectronic device also includes a second component directly attached to the second surface of the die pad through a second thermally conductive material. The first and second thermally conductive materials have thermal conductivities significantly greater than unfilled epoxy, that is, greater than 1 watt/meter-° K (W/m-° K). The first and second thermally conductive materials provide efficient thermal paths from the first component and the second component to the die pad.

At least a portion of the second component overlaps at least a portion of the first component, advantageously reducing a size of the microelectronic device. The microelectronic device further includes leads extending to an exterior of the microelectronic device. The leads are electrically conductive.

The microelectronic device includes a first thermal shunt connecting the die pad to a first lead of the leads. The first thermal shunt is closer to a center of the first component than to a center of the second component. The microelectronic device includes a second thermal shunt connecting the die pad to a second lead of the leads. The second thermal shunt is closer to a center of the second component than to a center of the first component. The first thermal shunt and the second thermal shunt have thermal conductivities significantly greater than filled epoxy, that is, greater than 100 W/m-° K. The first thermal shunt provides a first efficient thermal path from the first component through the first thermally conductive material, through the die pad, and through the first lead, compared to a comparable microelectronic device lacking the first thermal shunt. Similarly, the second thermal shunt provides a second efficient thermal path from the second component through the second thermally conductive material, through the die pad, and through the second lead, compared to a comparable microelectronic device lacking the second thermal shunt.

In another aspect, a microelectronic device includes a first die pad having a first surface and a second surface opposite from the first surface. The microelectronic device also includes a second die pad having a third surface and a fourth surface, opposite from the third surface. The third surface of the second die pad is coplanar with the first surface of the first die pad, and the fourth surface of the second die pad is coplanar with the second surface of the first die pad. The first and second die pads are electrically conductive. The microelectronic device includes a first component directly attached to the first surface of the first die pad through a first thermally conductive material. The microelectronic device also includes a second component directly attached to the fourth surface of the second die pad through a second thermally conductive material. At least a portion of the second component overlaps at least a portion of the first component, advantageously reducing a size of the microelectronic device. The microelectronic device further includes leads extending to an exterior of the microelectronic device. The leads are electrically conductive.

The microelectronic device includes a first thermal shunt connecting the first die pad to a first lead of the leads. The microelectronic device includes a second thermal shunt connecting the second die pad to a second lead of the leads. The first thermal shunt and the second thermal shunt have thermal conductivities greater than filled epoxy. The first thermal shunt provides a first efficient thermal path from the first component through the first thermally conductive material, through the first die pad, and through the first lead, compared to a comparable microelectronic device lacking the first thermal shunt. Similarly, the second thermal shunt provides an efficient thermal path from the second component through the second thermally conductive material, through the second die pad, and through the second lead, compared to a comparable microelectronic device lacking the second thermal shunt.

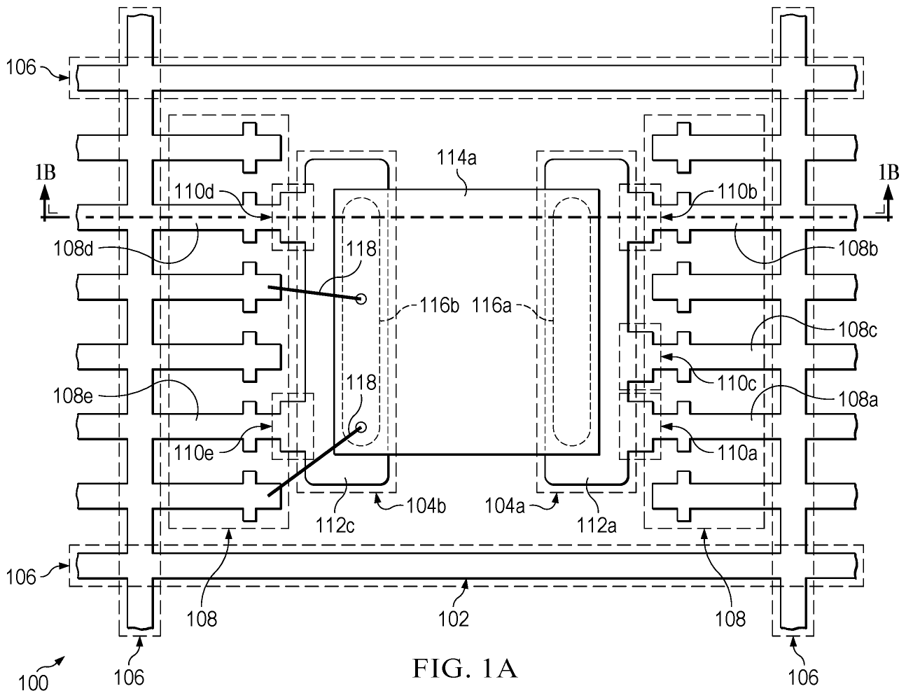

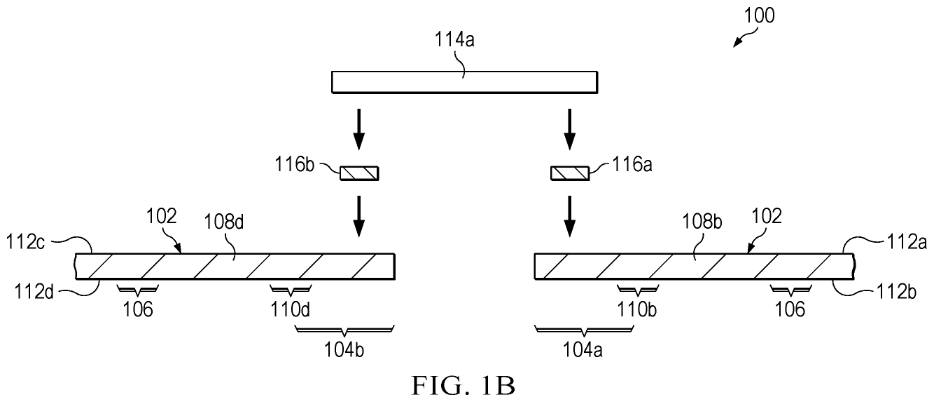

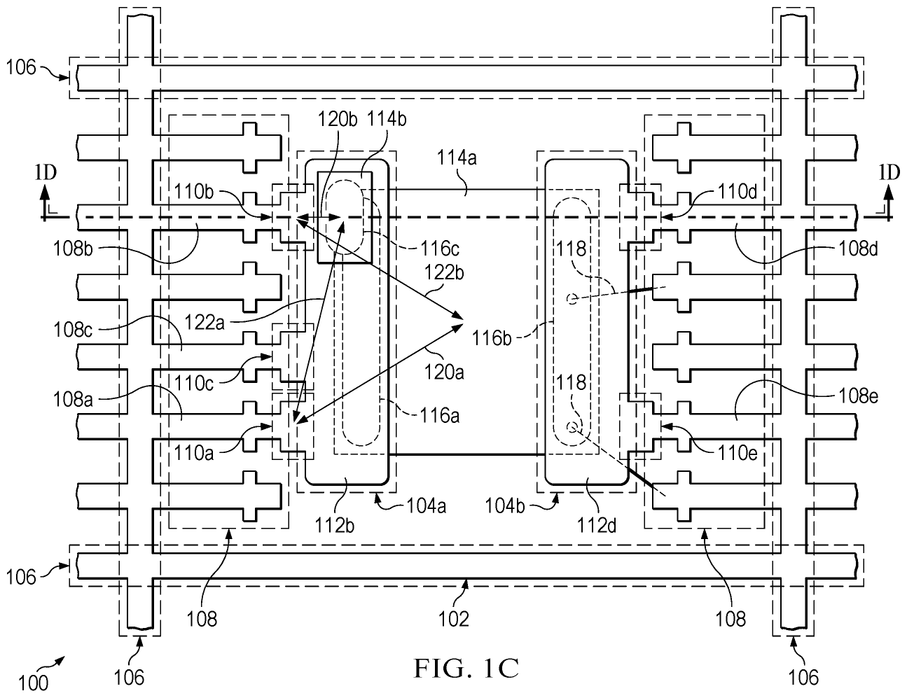

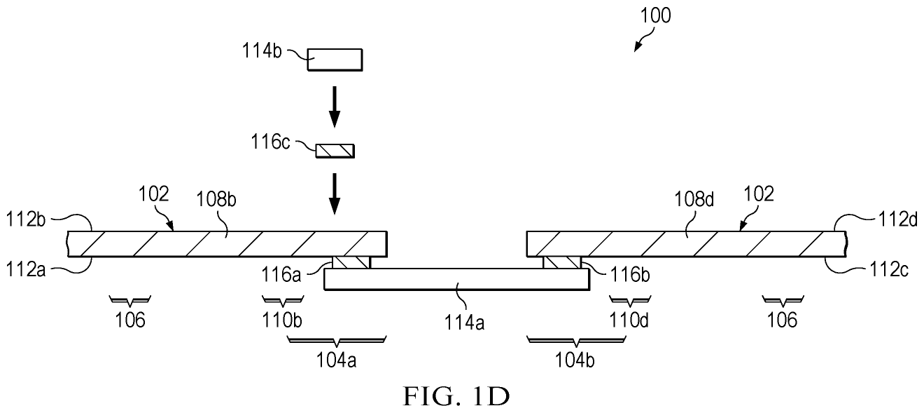

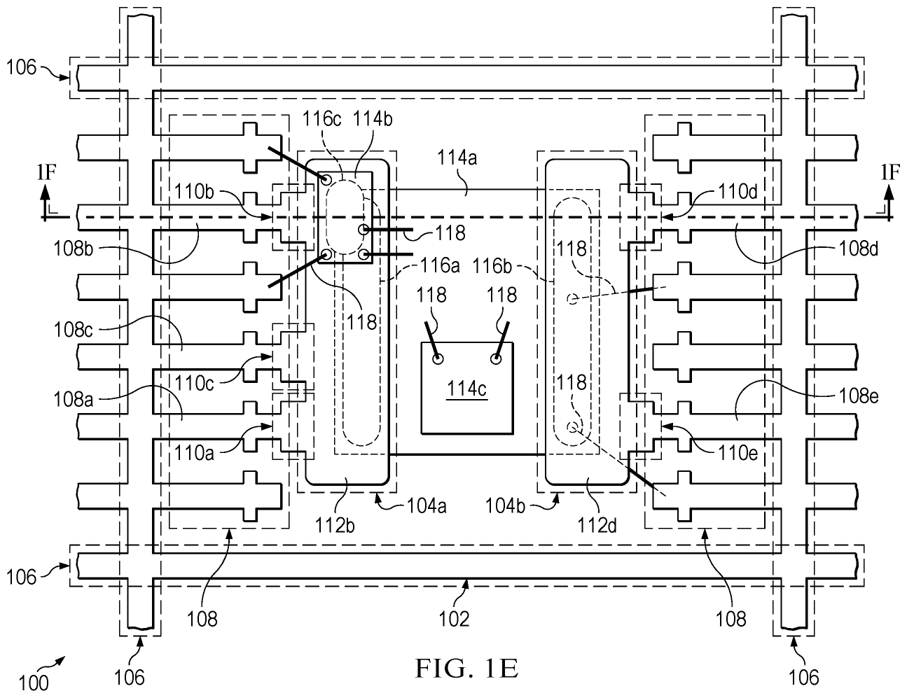

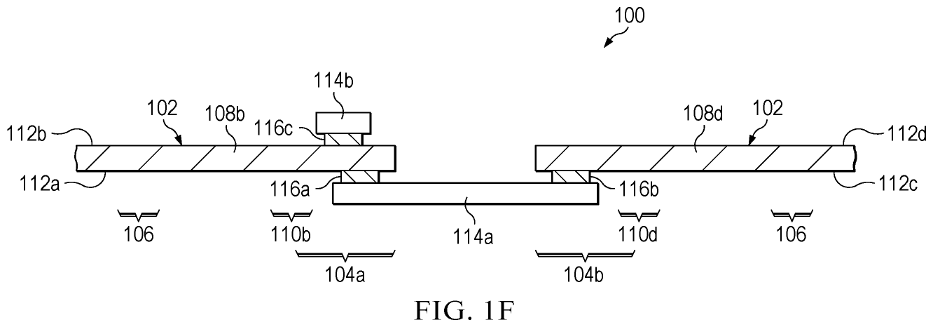

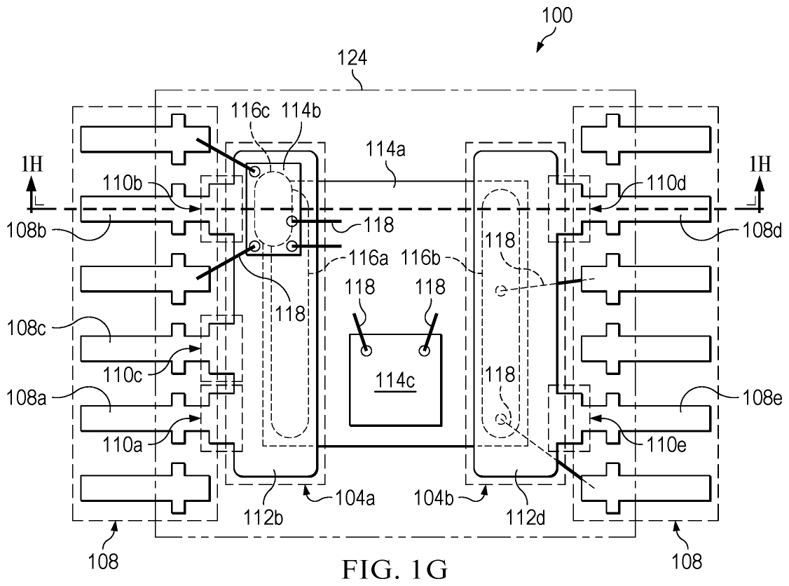

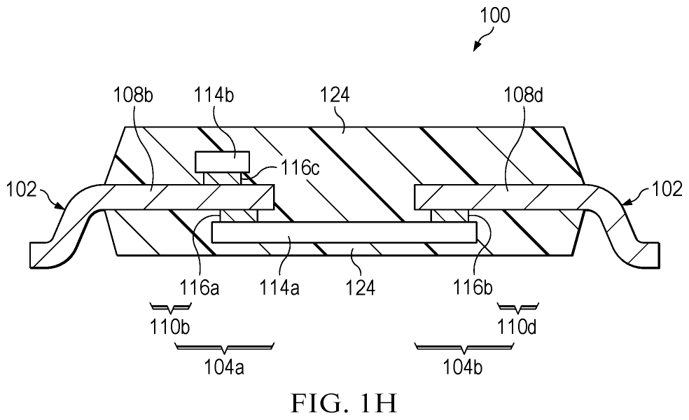

FIG. 1A through FIG. 1H are cross sections and top views of an example microelectronic device, depicted in stages of formation. Referring to FIG. 1A, a top view, and FIG. 1B, a cross section of FIG. 1A, the microelectronic device 100 is formed on a lead frame 102. The lead frame 102 is electrically conductive, and may include primarily copper. In this example, the lead frame 102 includes a first die pad 104a and may include a second die pad 104b. The lead frame 102 includes dam bars 106 and leads 108 contiguous with the dam bars 106, extending from the dam bars 106 toward the die pads 104a and 104b.

The lead frame 102 includes a first thermal shunt 110a connecting the first die pad 104a to a first lead 108a of the leads 108. The lead frame 102 includes a second thermal shunt 110b connecting the first die pad 104a to a second lead 108b of the leads 108. The lead frame 102 may further include additional thermal shunts, for example thermal shunts 110c, 110d, and 110e, connecting the first die pad 104a or the second die pad 104b to corresponding additional leads 108c, 108d, and 108e, respectively, of the leads 108. The thermal shunts 110a through 110e are contiguous with the die pads 104a and 104b, and are contiguous with the corresponding leads 108a through 108e, respectively. The thermal shunts 110a through 110e have thermal conductivities significantly greater than filled epoxy.

The die pads 104a and 104b, the leads 108, and the thermal shunts 110a through 110e may have a similar composition. For example, all elements of the lead frame 102 may have a core layer of copper or Alloy 42 (an iron-nickel alloy).

The first die pad 104a has a first surface 112a and a second surface 112b, opposite from the first surface 112a. The second die pad 104b has a third surface 112c and a fourth surface 112d, opposite from the third surface 112c. The first surface 112a and the third surface 112c are exposed in FIG. 1A, and are shown in cross section in FIG. 1B, while the second surface 112b and the fourth surface 112d are hidden in FIG. 1A by the first die pad 104a and the second die pad 104b, respectively, but are shown in cross section in FIG. 1B. The third surface 112c of the second die pad 104b is coplanar with the first surface 112a of the first die pad 104a, and the fourth surface 112d of the second die pad 104b is coplanar with the second surface 112b of the first die pad 104a.

A first component 114a is directly attached to the first surface 112a of the first die pad 104a, through a first thermally conductive material 116a. The first thermally conductive material 116a may be recessed from edges of the first component 114a, may be substantially coincident with the edges of the first component 114a, or may extend past the edges of the first component 114a. The first component 114a may also be directly attached to the third surface 112c of the second die pad 104b, through a second thermally conductive material 116b. The second thermally conductive material 116b may be recessed from edges of the first component 114a, may be substantially coincident with the edges of the first component 114a, or may extend past the edges of the first component 114a. The first surface 112a of the first die pad 104a being coplanar with the third surface 112c of the second die pad 104b may advantageously facilitate attaching the first component 114a to the first die pad 104a and the second die pad 104b. The first component 114a may be manifested as a transformer, a gallium nitride field effect transistor (GaN FET), a microprocessor, or an amplifier, by way of example. Other manifestations for the first component 114a are within the scope of this example. The first thermally conductive material 116a and the second thermally conductive material 116b may be implemented as an electrically conductive adhesive, an electrically insulating adhesive, or solder, by way of example. The first thermally conductive material 116a and the second thermally conductive material 116b may have a same composition, or may have different compositions.

A first portion of electrical connections 118 may be formed at this step. The first portion of the electrical connections 118 may electrically connect the first component 114a to one or more of the leads 108. The first portion of the electrical connections 118 may be implemented as wire bonds or ribbon bonds, by way of example.

Referring to FIG. 1C, a top view, and FIG. 1D, a cross section of FIG. 1C, a second component 114b is directly attached to the second surface 112b of the first die pad 104a, through a third thermally conductive material 116c. The third thermally conductive material 116c may be recessed from edges of the second component 114b, may be substantially coincident with the edges of the second component 114b, or may extend past the edges of the second component 114b. The microelectronic device 100 is shown as rotated 180 degrees about a vertical axis in the plane of FIG. 1C, with respect to the view of FIG. 1A. Similarly, the microelectronic device 100 is shown as rotated 180 degrees about an axis perpendicular to the plane of FIG. 1D, with respect to the view of FIG. 1B. Rotation of the microelectronic device 100 between attaching the first component 114a and attaching the second component 114b may replicate the method of forming the microelectronic device 100, wherein the first component 114a and the second component 114b are each attached in turn to an instant top surface of the lead frame 102. At least a portion of the second component 114b overlaps at least a portion of the first component 114a, accruing the advantage of reduced size for the microelectronic device 100.

In versions of this example in which the first component 114a is manifested as a transformer, the second component 114b may be manifested as a primary winding driver circuit or a secondary winding receiver circuit. In versions of this example in which the first component 114a is manifested as a GaN FET, the second component 114b may be manifested as a silicon metal oxide semiconductor field effect transistor (MOSFET) connected to the GaN FET in a cascode configuration. In versions of this example in which the first component 114a is manifested as a microprocessor, the second component 114b may be manifested as a memory management unit or a processor interface chip. In versions of this example in which the first component 114a is manifested as an amplifier, the second component 114b may be manifested as a matrix switch or a transconductor buffer. Other implementations for the second component 114b are within the scope of this example.

The third thermally conductive material 116c may be implemented as an electrically conductive adhesive, an electrically insulating adhesive, or solder, by way of example. The third thermally conductive material 116c may have a different composition than the first and second thermally conductive materials 116a and 116b. The thermally conductive materials 116a through 116c have thermal conductivities significantly greater than unfilled epoxy.

The first thermal shunt 110a is closer to a center of the first component 114a than to a center of the second component 114b, that is, a first distance 120a between the first thermal shunt 110a and the center of the first component 114a is less than an alternate distance 122a between the first thermal shunt 110a and the center of the second component 114b. Thus, the first thermal shunt 110a provides a first efficient thermal path from the first component 114a through the first thermally conductive material 116a, through the first die pad 104a, and through the first lead 108a, compared to a comparable microelectronic device lacking the first thermal shunt 110a. The second thermal shunt 110b is closer to a center of the second component 114b than to a center of the first component 114a, that is, a second distance 120b between the second thermal shunt 110b and the center of the second component 114b is less than an alternate distance 122b between the second thermal shunt 110b and the center of the first component 114a. Thus, the second thermal shunt 110b provides a second efficient thermal path from the second component 114b through the third thermally conductive material 116c, through the first die pad 104a, and through the second lead 108b, compared to a comparable microelectronic device lacking the second thermal shunt 110b. The additional thermal shunts 110c, 110d, and 110e, provide additional efficient thermal paths from the first component 114a through the corresponding leads 108c, 108d, and 108e that are contiguous with the additional thermal shunts 110c, 110d, and 110e, respectively.

Referring to FIG. 1E, a top view, and FIG. 1F, a cross section of FIG. 1E, a third component 114c may be attached to the first component 114a. The third component 114c may be implemented as a passive component, such as a filter, by way of example. The third component 114c may be attached to the first component 114a by adhesive or solder, by way of example.

A second portion of the electrical connections 118 may be formed to the first component 114a, the second component 114b, and the third component 114c at this step. The second portion of the electrical connections 118 may electrically connect any of the first component 114a, the second component 114b, and the third component 114c to one another or to one or more of the leads 108, or both. The second portion of the electrical connections 118 may be implemented as wire bonds or ribbons bonds, or a combination thereof.

Referring to FIG. 1G, a top view, and FIG. 1H, a cross section of FIG. 1G, an encapsulation material 124 is formed around the die pads 104a and 104b, the components 114a, 114b, and 114c, the electrical connections 118, the thermal shunts 110a through 110e, and portions of the leads 108 proximate to the die pads 104a and 104b. The leads 108 extend from the encapsulation material 124 to an exterior of the microelectronic device 100. The leads 108 are severed from the dam bars 106 of FIG. 1E and FIG. 1F. The leads 108 are shaped into gull wing configurations to provide a small outline integrated circuit (SOIC) package for the microelectronic device 100.

The encapsulation material 124 may be implemented as an epoxy compound, by way of example. The encapsulation material 124 may include filler particles of silicon dioxide or aluminum oxide to reduce a thermal expansion coefficient of the encapsulation material 124.

The microelectronic device 100 may be subsequently attached to a circuit substrate, such as a printed circuit board, not shown, in an electronic apparatus. Ends of the leads 108 external to the encapsulation material 124 may be attached to the circuit substrate by solder or an electrically conductive adhesive. The first thermal shunt 110a provides an efficient thermal path from the first component 114a through the first die pad 104a and the first lead 108a to the circuit substrate, advantageously reducing a temperature of the first component 114a during operation of the microelectronic device 100. Similarly, the second thermal shunt 110b provides an efficient thermal path from the second component 114b through the first die pad 104a and the second lead 108b to the circuit substrate, advantageously reducing a temperature of the second component 114b during operation of the microelectronic device 100.

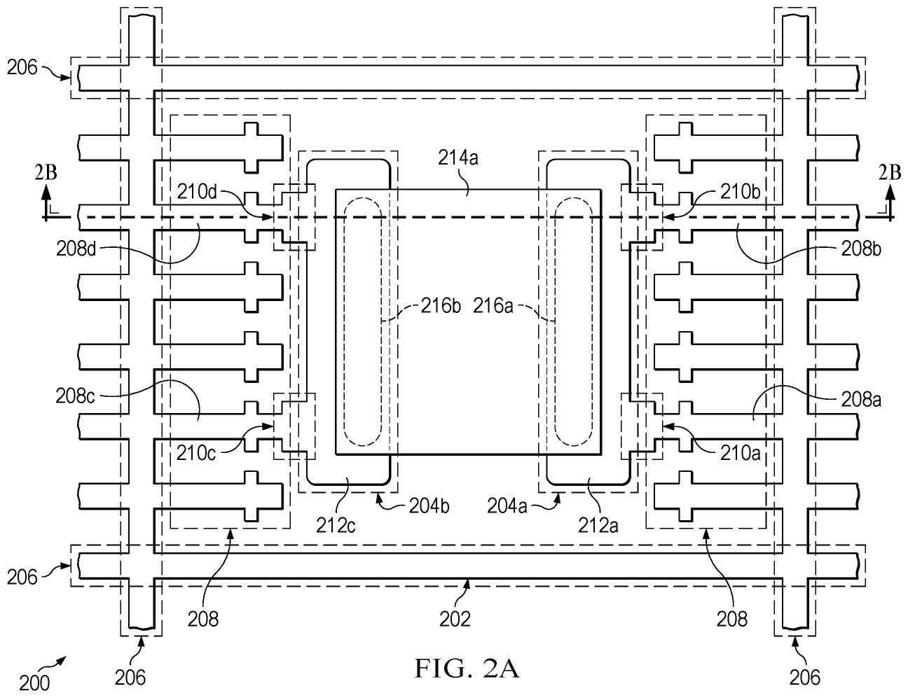

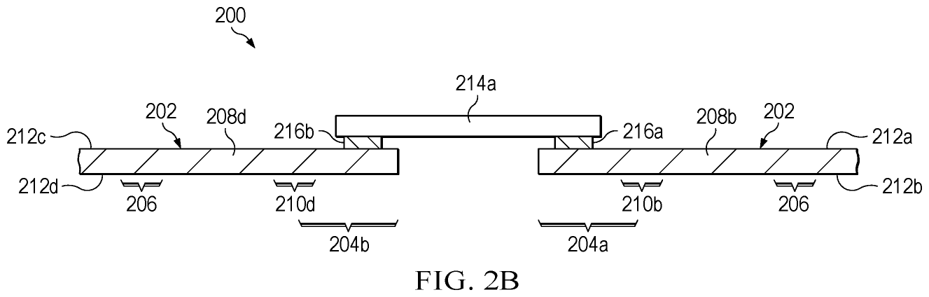

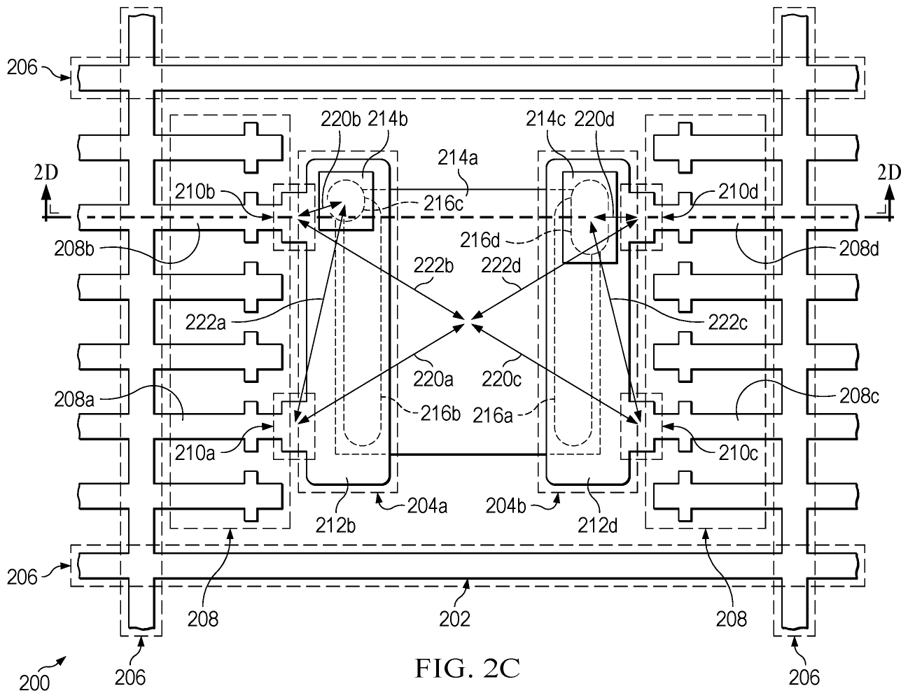

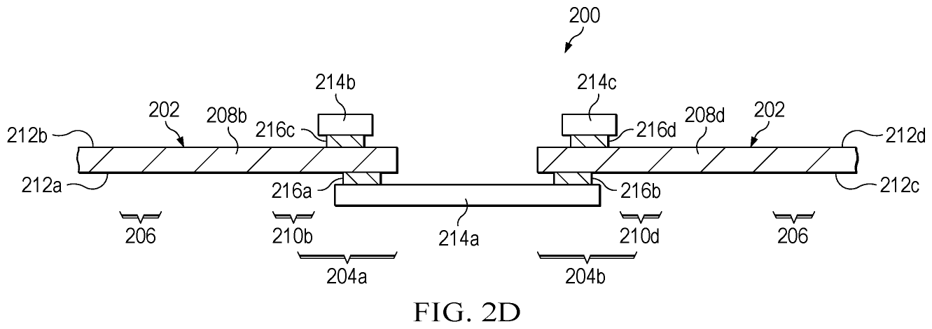

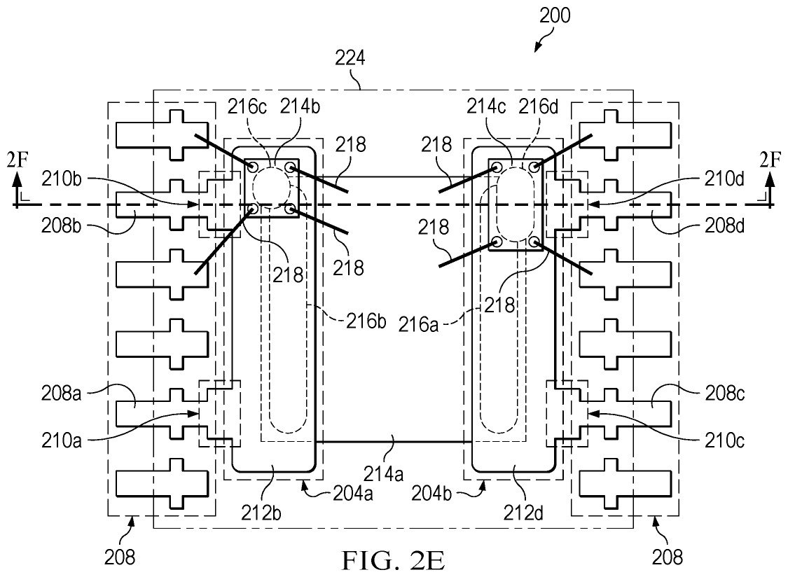

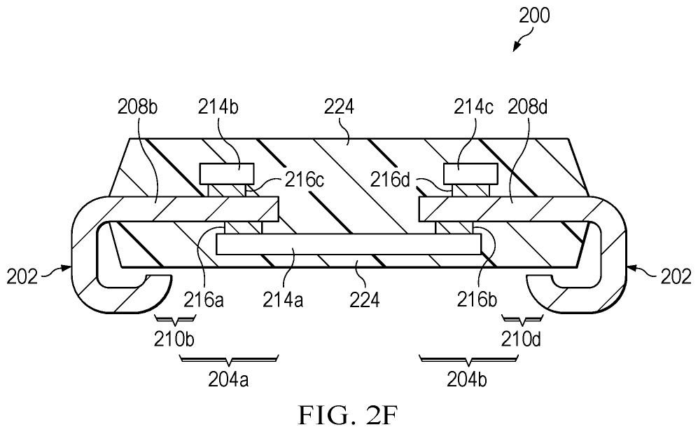

FIG. 2A through FIG. 2F are cross sections and top views of another example microelectronic device, depicted in stages of formation. Referring to FIG. 2A, a top view, and FIG. 2B, a cross section of FIG. 2A, the microelectronic device 200 is formed on a lead frame 202. The lead frame 202 is electrically conductive. In this example, the lead frame 202 includes a first die pad 204a and a second die pad 204b. The lead frame 202 includes dam bars 206 and leads 208 contiguous with the dam bars 206, extending from the dam bars 206 toward the die pads 204a and 204b.

The lead frame 202 includes a first thermal shunt 210a connecting the first die pad 204a to a first lead 208a of the leads 208. The lead frame 202 of this example includes a second thermal shunt 210b connecting the first die pad 204a to a second lead 208b of the leads 208. The lead frame 202 of this example further includes a third thermal shunt 210c connecting the second die pad 204b to a third lead 208c of the leads 208, and includes a fourth thermal shunt 210d connecting the second die pad 204b to a fourth lead 208d of the leads 208. The thermal shunts 210a through 210d are contiguous with the die pads 204a and 204b, and are contiguous with the corresponding leads 208a through 208d, respectively. The thermal shunts 210a through 210d have thermal conductivities significantly greater than filled epoxy.

The first die pad 204a has a first surface 212a and a second surface 212b, opposite from the first surface 212a. The second die pad 204b has a third surface 212c and a fourth surface 212d, opposite from the third surface 212c. The first surface 212a and the third surface 212c are exposed in FIG. 2A, and are shown in cross section in FIG. 2B, while the second surface 212b and the fourth surface 212d are hidden in FIG. 2A by the first die pad 204a and the second die pad 204b, respectively, but are shown in cross section in FIG. 2B. The third surface 212c of the second die pad 204b is coplanar with the first surface 212a of the first die pad 204a, and the fourth surface 212d of the second die pad 204b is coplanar with the second surface 212b of the first die pad 204a.

A first component 214a is directly attached to the first surface 212a of the first die pad 204a, through a first thermally conductive material 216a, and is directly attached to the third surface 212c of the second die pad 204b, through a second thermally conductive material 216b. The first surface 212a of the first die pad 204a being coplanar with the third surface 212c of the second die pad 204b may advantageously facilitate attaching the first component 214a to the first die pad 204a and the second die pad 204b. The first thermally conductive material 216a and the second thermally conductive material 216b may be implemented as an electrically conductive adhesive, an electrically insulating adhesive, or solder, by way of example.

Referring to FIG. 2C, a top view, and FIG. 2D, a cross section of FIG. 2C, the microelectronic device 200 is shown as rotated 180 degrees about a vertical axis in the plane of FIG. 2C, with respect to the view of FIG. 2A. Similarly, the microelectronic device 200 is shown as rotated 180 degrees about an axis perpendicular to the plane of FIG. 2D, with respect to the view of FIG. 2B. A second component 214b is directly attached to the second surface 212b of the first die pad 204a, through a third thermally conductive material 216c. At least a portion of the second component 214b overlaps at least a portion of the first component 214a, accruing the advantage of reduced size for the microelectronic device 200. A third component 214c is directly attached to the fourth surface 212d of the second die pad 204b, through a fourth thermally conductive material 216d. At least a portion of the third component 214c overlaps at least a portion of the first component 214a, accruing additional advantage of reduced size for the microelectronic device 200.

The first thermal shunt 210a is closer to a center of the first component 214a than to a center of the second component 214b, that is, a first distance 220a between the first thermal shunt 210a and the center of the first component 214a is less than an alternate distance 222a between the first thermal shunt 210a and the center of the second component 214b. Thus, the first thermal shunt 210a provides an efficient thermal path from the first component 214a through a first thermally conductive material 216a, through the first die pad 204a, and through the first lead 208a, compared to a comparable microelectronic device lacking the first thermal shunt 210a.

The second thermal shunt 210b is closer to a center of the second component 214b than to a center of the first component 214a, that is, a second distance 220b between the second thermal shunt 210b and the center of the second component 214b is less than an alternate distance 222b between the second thermal shunt 210b and the center of the first component 214a. Thus, the second thermal shunt 210b provides an efficient thermal path from the second component 214b through the third thermally conductive material 216c, through the first die pad 204a, and through the second lead 208b, compared to a comparable microelectronic device lacking the second thermal shunt 210b.

The third thermal shunt 210c is closer to the center of the first component 214a than to a center of the third component 214c, that is, a third distance 220c between the third thermal shunt 210c and the center of the first component 214a is less than an alternate distance 222c between the third thermal shunt 210c and the center of the third component 214c. Thus, the third thermal shunt 210c provides an efficient thermal path from the first component 214a through the second thermally conductive material 216b, through the second die pad 204b, and through the third lead 208c, compared to a comparable microelectronic device lacking the third thermal shunt 210c.

The fourth thermal shunt 210d is closer to a center of the third component 214c than to a center of the first component 214a, that is, a fourth distance 220d between the fourth thermal shunt 210d and the center of the third component 214c is less than an alternate distance 222d between the fourth thermal shunt 210d and the center of the first component 214a. Thus, the fourth thermal shunt 210d provides an efficient thermal path from the third component 214c through the fourth thermally conductive material 216d, through the second die pad 204b to the fourth lead 208d, compared to a comparable microelectronic device lacking the fourth thermal shunt 210d.

Referring to FIG. 2E, a top view, and FIG. 2F, a cross section of FIG. 2E, electrical connections 218 may be formed to the first component 214a, the second component 214b, and the third component 214c. The electrical connections 218 may electrically connect the second component 214b and the third component 214c to instances of the leads 208, and to the first component 214a, by way of example. Other configurations of the electrical connections 218 are within the scope of this example.

An encapsulation material 224 is formed around the die pads 204a and 204b, the components 214a, 214b, and 214c, the electrical connections 218, the thermal shunts 210a through 210d, and portions of the leads 208 proximate to the die pads 204a and 204b. The leads 208 extend from the encapsulation material 224 to an exterior of the microelectronic device 200. The leads 208 are severed from the dam bars 206 of FIG. 2C and FIG. 2D. The leads 208 are shaped into J-lead configurations to provide a J-lead package for the microelectronic device 200.

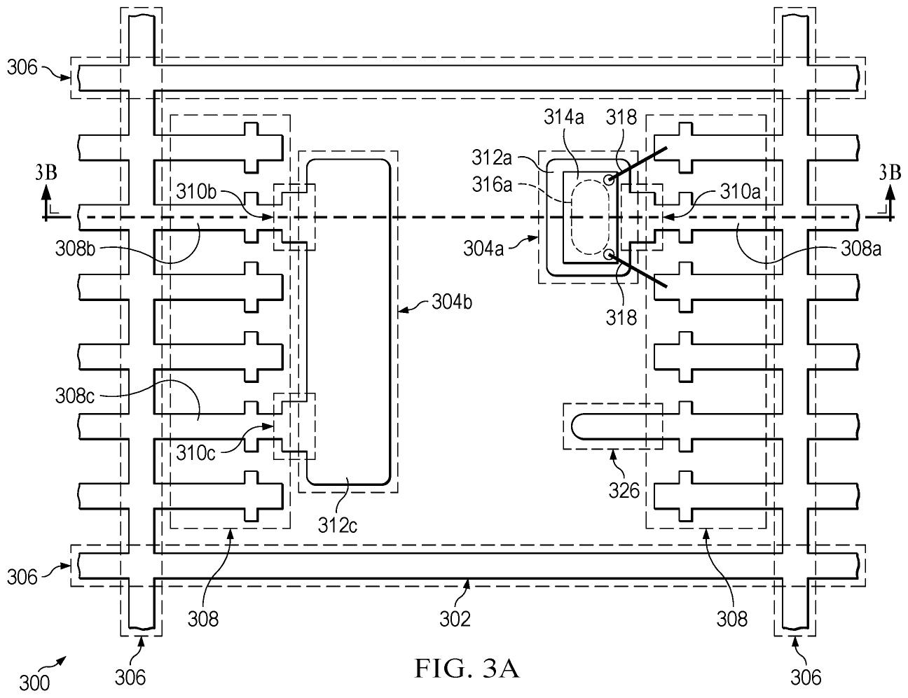

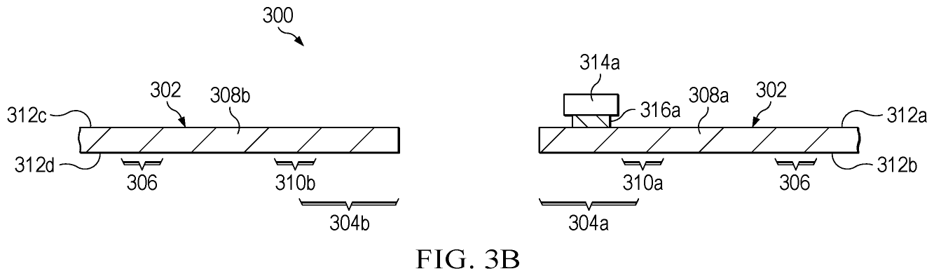

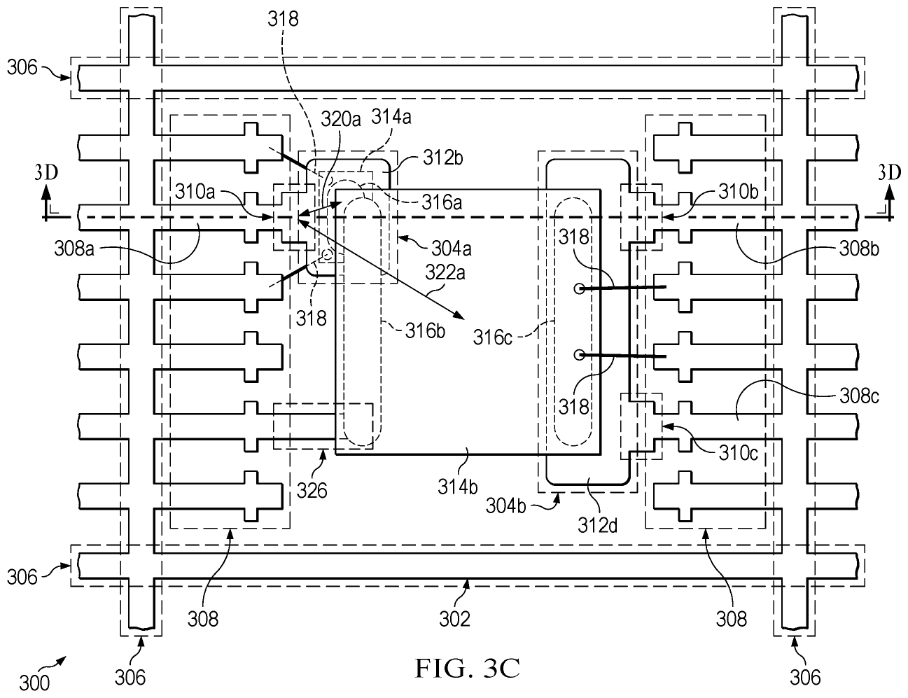

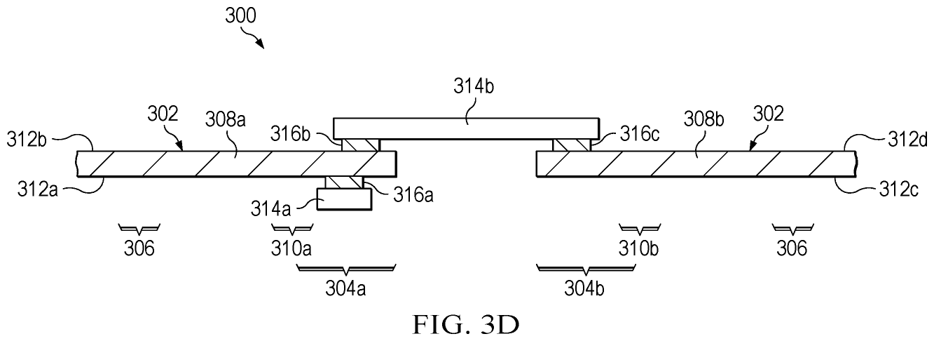

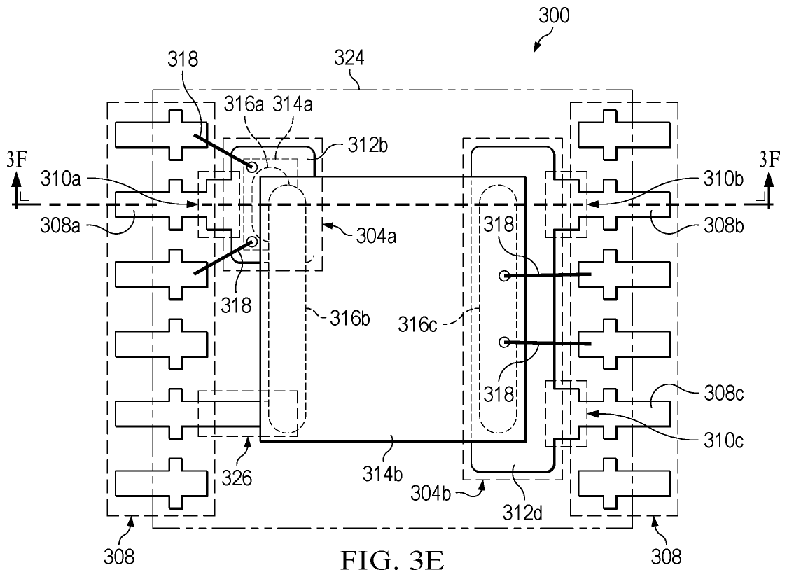

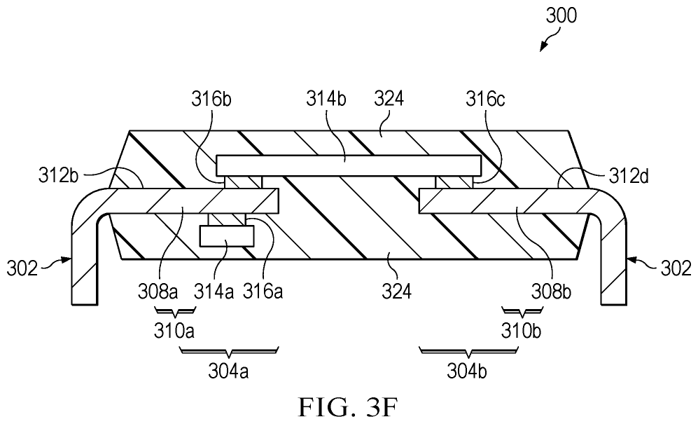

FIG. 3A through FIG. 3F are cross sections and top views of another example microelectronic device, depicted in stages of formation. Referring to FIG. 3A, a top view, and FIG. 3B, a cross section of FIG. 3A, the microelectronic device 300 is formed on a lead frame 302. The lead frame 302 is electrically conductive. In this example, the lead frame 302 includes a first die pad 304a and a second die pad 304b. The lead frame 302 of this example further includes a die support strut 326 located adjacent to the first die pad 304a and opposite from the second die pad 304b. The lead frame 302 includes dam bars 306 and leads 308 contiguous with the dam bars 306, extending from the dam bars 306 toward the die pads 304a and 304b.

The lead frame 302 includes a first thermal shunt 310a connecting the first die pad 304a to a first lead 308a of the leads 308. The lead frame 302 of this example includes a second thermal shunt 310b connecting the first die pad 304a to a second lead 308b of the leads 308. The lead frame 302 of this example further includes a third thermal shunt 310c connecting the second die pad 304b to a third lead 308c of the leads 308. The thermal shunts 310a through 310c are contiguous with the die pads 304a and 304b, and are contiguous with the corresponding leads 308a through 308c, respectively. The thermal shunts 310a through 310c have thermal conductivities significantly greater than filled epoxy.

The first die pad 304a has a first surface 312a and a second surface 312b, opposite from the first surface 312a. The second die pad 304b has a third surface 312c and a fourth surface 312d, opposite from the third surface 312c. The first surface 312a and the third surface 312c are exposed in FIG. 3A, and are shown in cross section in FIG. 3B, while the second surface 312b and the fourth surface 312d are hidden in FIG. 3A by the first die pad 304a and the second die pad 304b, respectively, but are shown in cross section in FIG. 3B. The third surface 312c of the second die pad 304b is coplanar with the first surface 312a of the first die pad 304a, and the fourth surface 312d of the second die pad 304b is coplanar with the second surface 312b of the first die pad 304a.

A first component 314a is directly attached to the first surface 312a of the first die pad 304a, through a first thermally conductive material 316a. A first portion of electrical connections 318 may be formed at this step. The first portion of the electrical connections 318 may electrically connect the first component 314a to one or more of the leads 308.

Referring to FIG. 3C, a top view, and FIG. 3D, a cross section of FIG. 3C, the microelectronic device 300 is shown as rotated 180 degrees about a vertical axis in the plane of FIG. 3C, with respect to the view of FIG. 3A. Similarly, the microelectronic device 300 is shown as rotated 180 degrees about an axis perpendicular to the plane of FIG. 3D, with respect to the view of FIG. 3B. A second component 314b is directly attached to the second surface 312b of the first die pad 304a, through a second thermally conductive material 316b and is directly attached to the fourth surface 312d of the second die pad 304b, through a third thermally conductive material 316c. The second surface 312b of the first die pad 304a being coplanar with the fourth surface 312d of the second die pad 304b may advantageously facilitate attaching the second component 314b to the first die pad 304a and the second die pad 304b. At least a portion of the second component 314b overlaps at least a portion of the first component 314a, accruing the advantage of reduced size for the microelectronic device 300. The second component 314b may be attached to the die support strut 326 to provide stability while attaching the second component 314b to the first die pad 304a and the second die pad 304b.

The first thermal shunt 310a is closer to a center of the first component 314a than to a center of the second component 314b, that is, a first distance 320a between the first thermal shunt 310a and the center of the first component 314a is less than an alternate distance 322a between the first thermal shunt 310a and the center of the second component 314b. Thus, the first thermal shunt 310a provides an efficient thermal path from the first component 314a through the first thermally conductive material 316a, through the first die pad 304a, and through the first lead 308a, compared to a comparable microelectronic device lacking the first thermal shunt 310a.

In this example, the second component 314b is the only component attached to the second die pad 304b. Thus, the second thermal shunt 310b provides an efficient thermal path from the second component 314b through the third thermally conductive material 316c, through the second die pad 304b, and through the second lead 308b, compared to a comparable microelectronic device lacking the second thermal shunt 310b. Similarly, the third thermal shunt 310c provides an efficient thermal path from the second component 314b through the second thermally conductive material 316b, through the second die pad 304b, and through the third lead 308c, compared to a comparable microelectronic device lacking the third thermal shunt 310c.

A second portion of the electrical connections 318 may be formed at this step. The second portion of the electrical connections 318 may electrically connect the second component 314b to one or more of the leads 308. Other configurations of the electrical connections 318 are within the scope of this example.

Referring to FIG. 3E, a top view, and FIG. 3F, a cross section of FIG. 3E, an encapsulation material 324 is formed around the die pads 304a and 304b, the components 314a and 314b, the electrical connections 318, the thermal shunts 310a through 310c, and portions of the leads 308 proximate to the die pads 304a and 304b. The leads 308 extend from the encapsulation material 324 to an exterior of the microelectronic device 300. The leads 308 are severed from the dam bars 306 of FIG. 3C and FIG. 3D. The leads 308 are shaped into straight lead configurations to provide a dual inline package (DIP) for the microelectronic device 300.

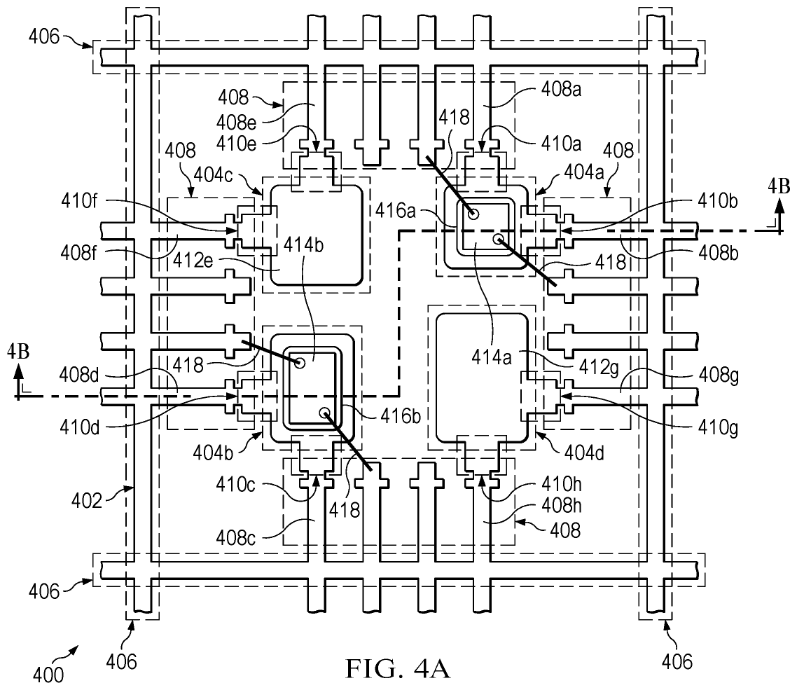

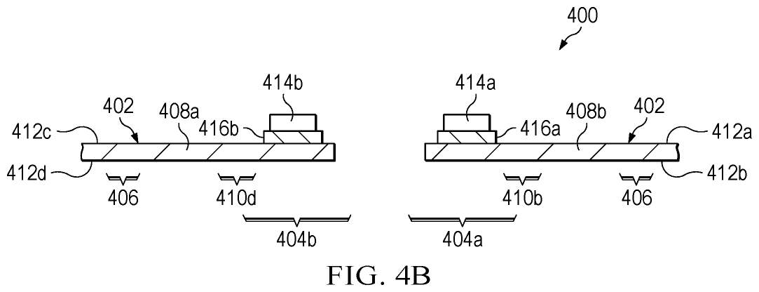

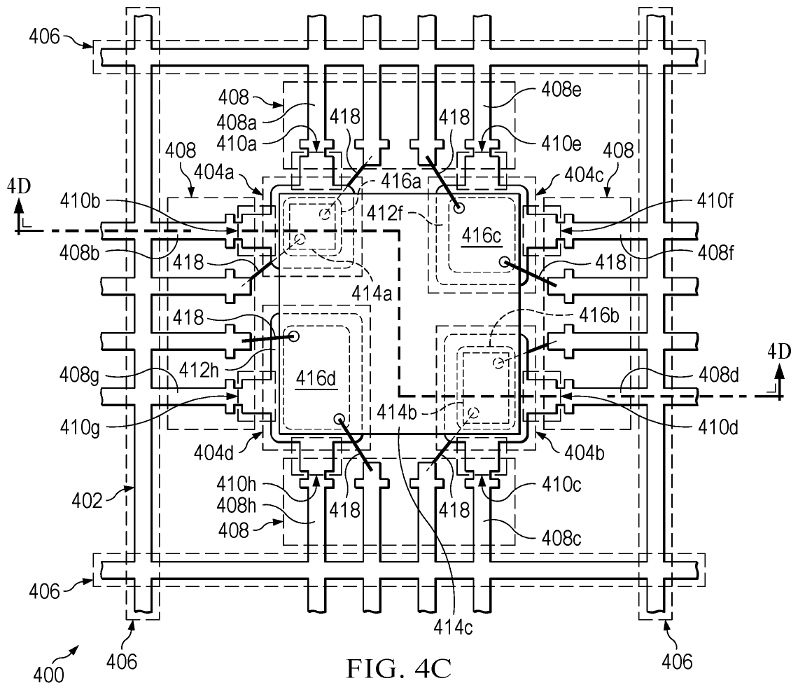

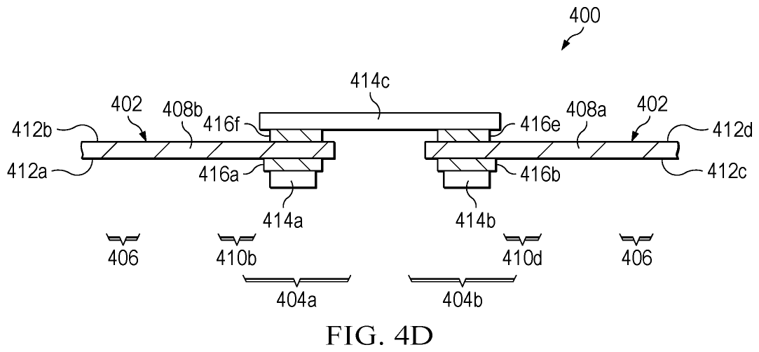

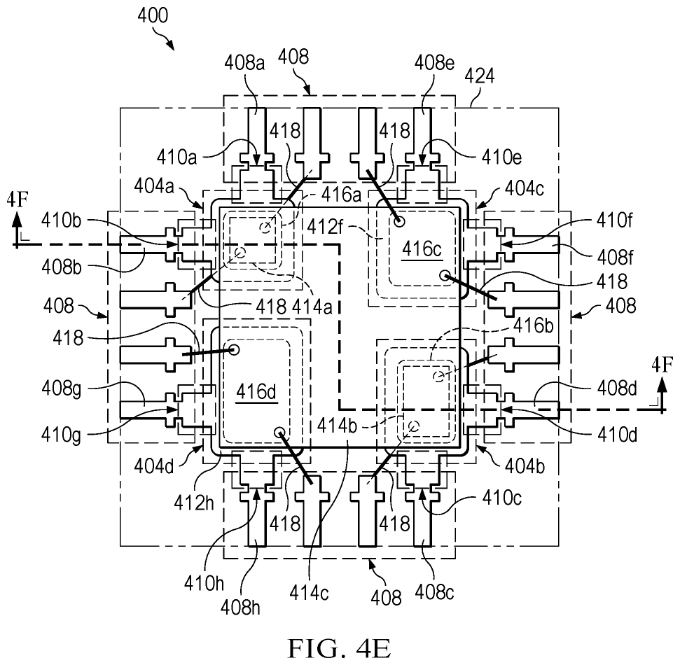

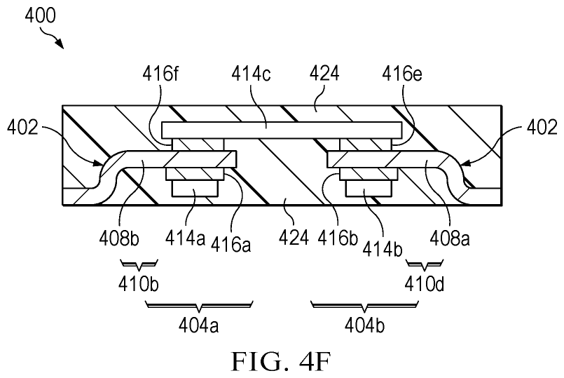

FIG. 4A through FIG. 4F are cross sections and top views of another example microelectronic device, depicted in stages of formation. Referring to FIG. 4A, a top view, and FIG. 4B, a cross section of FIG. 4A, the microelectronic device 400 is formed on a lead frame 402. The lead frame 402 is electrically conductive. In this example, the lead frame 402 includes a first die pad 404a, a second die pad 404b, a third die pad 404c, and a fourth die pad 404d. The lead frame 402 includes dam bars 406 and leads 408 contiguous with the dam bars 406, extending from the dam bars 406 toward the die pads 404a through 404d.

In this example, each of the die pads 404a through 404d are connected to two specific leads 408a through 408h of the leads 408 through two thermal shunts 410a through 410h, respectively. The lead frame 402 includes a first thermal shunt 410a and a second thermal shunt 410b connecting the first die pad 404a to a first lead 408a and a second lead 408b of the leads 408, respectively. The lead frame 402 includes a third thermal shunt 410c and a fourth thermal shunt 410d connecting the second die pad 404b to a third lead 408c and a fourth lead 408d of the leads 408, respectively. The lead frame 402 includes a fifth thermal shunt 410e and a sixth thermal shunt 410f connecting the third die pad 404c to a fifth lead 408e and a sixth lead 408f of the leads 408, respectively. The lead frame 402 includes a seventh thermal shunt 410g and an eighth thermal shunt 410h connecting the fourth die pad 404d to a seventh lead 408g and an eighth lead 408h of the leads 408, respectively. The thermal shunts 410a through 410h are contiguous with the corresponding die pads 404a through 404d, and are contiguous with the corresponding leads 408a through 408h, respectively. The thermal shunts 410a through 410h have thermal conductivities significantly greater than filled epoxy.

The first die pad 404a has a first surface 412a and a second surface 412b, opposite from the first surface 412a. The second die pad 404b has a third surface 412c and a fourth surface 412d, opposite from the third surface 412c. The third die pad 404c has a fifth surface 412e and a sixth surface 412f, opposite from the fifth surface 412e. The fourth die pad 404d has a seventh surface 412g and an eighth surface 412h, opposite from the seventh surface 412g.

The first surface 412a, the third surface 412c, the fifth surface 412e, and the seventh surface 412g are exposed in FIG. 4A, while the second surface 412b, the fourth surface 412d, the sixth surface 412f, and the eighth surface 412h are hidden in FIG. 4A by the die pads 404a through 404d, respectively. The first surface 412a, the second surface 412b, the third surface 412c, and the fourth surface 412d are shown in cross section in FIG. 4B. The first surface 412a, the third surface 412c, the fifth surface 412e, and the seventh surface 412g are coplanar, and the second surface 412b, the fourth surface 412d, the sixth surface 412f, and the eighth surface 412h are coplanar.

A first component 414a is directly attached to the first surface 412a of the first die pad 404a, through a first thermally conductive material 416a. A second component 414b is directly attached to the third surface 412c of the second die pad 404b, through a second thermally conductive material 416b.

A first portion of electrical connections 418 may be formed at this step. The first portion of the electrical connections 418 may electrically connect the first component 414a and/or the second component 414b to one or more of the leads 408.

Referring to FIG. 4C, a top view, and FIG. 4D, a cross section of FIG. 4C, the microelectronic device 400 is shown as rotated 180 degrees about a vertical axis in the plane of FIG. 4C, with respect to the view of FIG. 4A. Similarly, the microelectronic device 400 is shown as rotated 180 degrees about an axis perpendicular to the plane of FIG. 4D, with respect to the view of FIG. 4B. A third component 414c is directly attached to the sixth surface 412f of the third die pad 404c, through a third thermally conductive material 416c, and is directly attached to the eighth surface 412h of the fourth die pad 404d, through a fourth thermally conductive material 416d. The third component 414c may also be directly attached to the second surface 412b of the first die pad 404a, through a fifth thermally conductive material 416e, and/or may be directly attached to the fourth surface 412d of the second die pad 404b, through a sixth thermally conductive material 416f. To improve readability of FIG. 4C, the fifth thermally conductive material 416e and the sixth thermally conductive material 416f are not shown in FIG. 4C, but are shown in cross section in FIG. 4D.

At least a portion of the third component 414c overlaps at least a portion of the first component 414a, accruing the advantage of reduced size for the microelectronic device 400. At least a portion of the third component 414c may overlap at least a portion of the second component 414b, accruing additional advantage of reduced size for the microelectronic device 400.

The first thermal shunt 410a and the second thermal shunt 410b are closer to a center of the first component 414a than to a center of the third component 414c. Thus, the first thermal shunt 410a and the second thermal shunt 410b provide a first efficient thermal path from the first component 414a through the first thermally conductive material 416a, through the first die pad 404a, and through the first lead 408a and the second lead 408b, respectively, compared to a comparable microelectronic device lacking the first thermal shunt 410a and the second thermal shunt 410b.

The third thermal shunt 410c and the fourth thermal shunt 410d are closer to a center of the second component 414b than to a center of the third component 414c. Thus, the third thermal shunt 410c and the fourth thermal shunt 410d provide a second efficient thermal path from the second component 414b through the second thermally conductive material 416b, through the second die pad 404b, and through the third lead 408c and the fourth lead 408d, respectively, compared to a comparable microelectronic device lacking the third thermal shunt 410c and the fourth thermal shunt 410d.

In this example, the third component 414c is the only component attached to the third die pad 404c. Thus, the fifth thermal shunt 410e and the sixth thermal shunt 410f provide a third efficient thermal path from the third component 414c through the third thermally conductive material 416c, through the third die pad 404c, and through the fifth lead 408e and the sixth lead 408f, respectively, compared to a comparable microelectronic device lacking the fifth thermal shunt 410e and the sixth thermal shunt 410f. Similarly, the third component 414c is the only component attached to the fourth die pad 404d. Thus, the seventh thermal shunt 410g and the eighth thermal shunt 410h provide a fourth efficient thermal path from the third component 414c through the fourth thermally conductive material 416d, through the fourth die pad 404d, and through the seventh lead 408g and the eighth lead 408h, respectively, compared to a comparable microelectronic device lacking the seventh thermal shunt 410g and the eighth thermal shunt 410h.

A second portion of the electrical connections 418 may be formed at this step. The second portion of the electrical connections 418 may electrically connect the third component 414c to one or more of the leads 408. Other configurations of the electrical connections 418 are within the scope of this example.

Referring to FIG. 4E, a top view, and FIG. 4F, a cross section of FIG. 4E, the leads 408 are severed from the dam bars 406 of FIG. 4C and FIG. 4D. The leads 408 are shaped to extend past the first component 414a and the second component 414b, as indicated in FIG. 4F. An encapsulation material 424 is formed around the die pads 404a and 404b, the components 414a, 414b, and 414c, the electrical connections 418, the thermal shunts 410a through 410e, and portions of the leads 408 proximate to the die pads 404a and 404b. The leads 408 extend through the encapsulation material 424 and are exposed at a bottom surface of the microelectronic device 400, to provide a quad flat no-lead (QFN) package for the microelectronic device 400.

Various features of the examples disclosed herein may be combined in other manifestations of example microelectronic devices. For example, the microelectronic devices 100, 200, 300, and 400 may be configured as SOIC packages, as J-lead packages, as DIPs, or as QFN packages. The microelectronic devices 100, 200, 300, and 400 may include one or more components attached to another component, as disclosed in reference to the third component 114c of FIG. 1E and FIG. 1F. The microelectronic devices 100, 200, 300, and 400 may include electrical connections 118, 218, 318, and 418, respectively, between components and leads, or between two components, in any configuration.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above described embodiments. Rather, the scope of the disclosure should be defined in accordance with the following claims and their equivalents.

What is claimed is:

1. A microelectronic device, comprising:
a die pad having a first surface and a second surface opposite from the first surface, the die pad being electrically conductive;
a first component directly attached to the first surface of the die pad through a first thermally conductive material;
a second component directly attached to the second surface of the die pad through a second thermally conductive material, wherein at least a portion of the second component overlaps at least a portion of the first component;
leads extending to an exterior of the microelectronic device, the leads being electrically conductive;
a first thermal shunt connecting the die pad to a first lead of the leads, the first thermal shunt being electrically conductive, wherein the first thermal shunt is closer to a center of the first component than to a center of the second component; and
a second thermal shunt connecting the die pad to a second lead of the leads, the second thermal shunt being electrically conductive, wherein the second thermal shunt is closer to the center of the second component than to the center of the first component.

2. The microelectronic device of claim 1, wherein the die pad is a first die pad, and further including:
a second die pad having a third surface and a fourth surface opposite from the third surface, the second die pad being electrically conductive, wherein the first component is directly attached to the third surface of the second die pad through a third thermally conductive material; and
a third thermal shunt connecting the second die pad to a third lead of the leads, the third thermal shunt being electrically conductive, wherein the third thermal shunt is closer to the center of the first component than to the center of the second component.

3. The microelectronic device of claim 2, further including:
a third component directly attached to the fourth surface of the second die pad through a fourth thermally conductive material, wherein at least a portion of the third component overlaps at least a portion of the first component; and
a fourth thermal shunt connecting the second die pad to a fourth lead of the leads, the fourth thermal shunt being electrically conductive, wherein the fourth thermal shunt is closer to a center of the third component than to the center of the first component.

4. The microelectronic device of claim 1, further including an additional component attached to the first component.

5. The microelectronic device of claim 1, wherein the die pad, the first thermal shunt, the second thermal shunt, and the leads are elements of a lead frame.

6. A method of forming a microelectronic device, comprising:
providing a lead frame having a die pad, leads, a first thermal shunt connecting the die pad to a first lead of the leads, and a second thermal shunt connecting the die pad to a second lead of the leads;
attaching a first component to a first surface of the die pad through a first thermally conductive material; and
attaching a second component to a second surface of the die pad, opposite from the first surface, through a second thermally conductive material; wherein:
the die pad, the leads, the first thermal shunt, and the second thermal shunt are electrically conductive;
at least a portion of the second component overlaps at least a portion of the first component;
the first thermal shunt is closer to a center of the first component than to a center of the second component; and
the second thermal shunt is closer to a center of the second component than to a center of the first component.

7. The method of claim 6, wherein:
the die pad is a first die pad;
the lead frame includes a second die pad having a third surface and a fourth surface opposite from the third surface; and
the lead frame includes a third thermal shunt connecting the second die pad to a third lead of the leads; and
further including attaching the first component to the third surface of the die pad through a third thermally conductive material; wherein:
the second die pad is electrically conductive;
the third thermal shunt is electrically conductive; and
the third thermal shunt is closer to the center of the first component than to the center of the second component.

8. The method of claim 7, wherein the lead frame includes a fourth thermal shunt connecting the second die pad to a fourth lead of the leads, the fourth thermal shunt being electrically conductive; and
further including attaching a third component directly to the fourth surface of the second die pad through a fourth thermally conductive material, at least a portion of the third component overlapping at least a portion of the first component, wherein the fourth thermal shunt is closer to a center of the third component than to a center of the first component.

9. The method of claim 6, further including attaching an additional component to the first component.

10. The method of claim 6, wherein attaching the first component to the die pad is performed prior to attaching the second component to the die pad.

11. A microelectronic device, comprising:
a first die pad having a first surface and a second surface opposite from the first surface, the first die pad being electrically conductive;
a first component directly attached to the first surface of the first die pad through a first thermally conductive material;
a second die pad having a third surface and a fourth surface opposite from the third surface, the third surface being coplanar with the first surface of the first die pad and the fourth surface being coplanar with the second surface of the first die pad, the second die pad being electrically conductive;
a second component directly attached to the fourth surface of the second die pad through a second thermally conductive material, wherein at least a portion of the second component overlaps at least a portion of the first component;
leads extending to an exterior of the microelectronic device, the leads being electrically conductive;
a first thermal shunt connecting the first die pad to a first lead of the leads, the first thermal shunt being electrically conductive; and
a second thermal shunt connecting the second die pad to a second lead of the leads, the second thermal shunt being electrically conductive.

12. The microelectronic device of claim 11, further including:
a third die pad having a fifth surface and a sixth surface opposite from the fifth surface, the fifth surface being coplanar with the first surface of the first die pad and the sixth surface being coplanar with the second surface of the first die pad, the third die pad being electrically conductive, wherein the first component is directly attached to the fifth surface of the third die pad through a third thermally conductive material; and
a third thermal shunt connecting the third die pad to a third lead of the leads, the third thermal shunt being electrically conductive.

13. The microelectronic device of claim 12, further including:
a fourth die pad having a seventh surface and an eighth surface opposite from the seventh surface, the seventh surface being coplanar with the first surface of the first die pad and the eighth surface being coplanar with the second surface of the first die pad, the fourth die pad being electrically conductive;
a third component directly attached to the seventh surface of the fourth die pad through a fourth thermally conductive material, wherein at least a portion of the third component overlaps at least a portion of the first component; and
a fourth thermal shunt connecting the fourth die pad to a fourth lead of the leads, the fourth thermal shunt being electrically conductive.

14. The microelectronic device of claim 11, further including a component attached to the first component.

15. The microelectronic device of claim 11, wherein the first die pad, the second die pad, the first thermal shunt, the second thermal shunt, and the leads are elements of a lead frame.

16. A method of forming a microelectronic device, comprising:
providing a lead frame having a first die pad, a second die pad, leads, a first thermal shunt connecting the first die pad to a first lead of the leads, and a second thermal shunt connecting the second die pad to a second lead of the leads; wherein:
the leads, the first and second die pads, and the first and second thermal shunts are electrically conductive;
the first die pad has a first surface and a second surface opposite from the first surface; and
the second die pad has a third surface coplanar with the first surface of the first die pad and a fourth surface opposite from the first surface, the fourth surface being coplanar with the second surface of the first die pad;
attaching a first component to the first surface of the first die pad through a first thermally conductive material; and
attaching a second component to the fourth surface of the second die pad through a second thermally conductive material, wherein at least a portion of the second component overlaps at least a portion of the first component.

17. The method of claim 16, wherein:
the lead frame includes a third die pad having a fifth surface and a sixth surface opposite from the fifth surface, the fifth surface being coplanar with the first surface of the first die pad, the third die pad being electrically conductive; and
the lead frame includes a third thermal shunt connecting the third die pad to a third lead of the leads, the third thermal shunt being electrically conductive; and
further including attaching the first component directly to the fifth surface of the third die pad through a third thermally conductive material.

18. The method of claim 17, wherein the lead frame includes a fourth die pad having a seventh surface and an eighth surface opposite from the seventh surface, the seventh surface being coplanar with the first surface of the first die pad and the eighth surface being coplanar with the second surface of the first die pad, the fourth die pad being electrically conductive, and the lead frame includes a fourth thermal shunt connecting the fourth die pad to a fourth lead of the leads, the fourth thermal shunt being electrically conductive; and
further including attaching a third component directly to the seventh surface of the fourth die pad through a fourth thermally conductive material, wherein at least a portion of the third component overlaps at least a portion of the first component.

19. The method of claim 16, further including directly attaching an additional component to the first component.

20. The method of claim 16, wherein attaching the first component to the first die pad is performed prior to attaching the second component to the second die pad.
